(19) United States
(12) Patent Application Publication
(10) Pub. No.: US 2006/0237788 A1
(43) Pub. Date: Oct. 26, 2006

(54) Semiconductor device and its fabrication method

(75) Inventor: Kazunari Ishimaru, Yokohama-shi (JP)

Correspondence Address: FOLEY AND LARDNER LLP;SUITE 500, 3000 K STREET NW, WASHINGTON, DC, 20007, US

(73) Assignee: KABUSHIKI KAISHA TOSHIBA

(21) Appl. No.: 11/364,552

(22) Filed: Mar. 1, 2006

(30) Foreign Application Priority Data
Mar. 2, 2005 (JP) 2005-056971

(51) Int. Cl. H01L 27/12

(52) U.S. Cl. 257/347

(57) ABSTRACT

A semiconductor device has a semiconductor substrate, a first MOSFET which has a first gate insulating film made of a high dielectric material formed above the semiconductor substrate and a first gate electrode formed above the first gate insulating film, an insulating film which is formed directly on sidewalls of the first gate electrode and made of a material having dielectric constant smaller than that of the first gate insulating film, and a second MOSFET which has a second gate insulating film made of a material having dielectric constant smaller than that of the first gate insulating film formed above the semiconductor substrate and a second gate electrode formed above the second gate insulating film, wherein the first gate electrode is formed of a first silicide or a first metal; and the second gate electrode is formed including a film made of at least one of polysilicon, amorphous silicon, polysilicon germanium and amorphous silicon germanium.

### CROSS REFERENCE TO RELATED APPLICATIONS

This application is based upon and claims the benefit of priority from the prior Japanese Patent Application No. 2005-56971, filed on Mar. 2, 2005, the entire contents of which are incorporated herein by reference.

### BACKGROUND OF THE INVENTION

1. Field of the Invention

The present invention relates to a gate electrode and a gate insulating film of a semiconductor device such as a MOSFET.

2. Related Art

In a MOSFET used for a semiconductor device such as an LSI, device size tends to be miniaturized in order to realize high integration of the devices, low cost and high performance. A thickness of a gate insulating film is also scaled down in the same way. However, when a physical film thickness indicating an actual thickness becomes 2 nm or less, current flows from a gate electrode through a substrate due to a tunnel phenomenon. To decrease the gate leak current, it is necessary to increase the physical film thickness.

To operate the MOSFET in a minute gate length region, it is necessary to decrease the thickness of the gate insulating film. Decrease of the gate insulating film thickness has a relationship of a tradeoff with decrease of the leak current. However, decrease of the gate insulating film thickness is equivalent to decrease of an electrical insulting film thickness. Therefore, even if a physical film thickness is large, it is possible to decrease an electrical film thickness by increasing a dielectric constant of the film.

Various materials have been studied as materials of a high-k gate insulating film, and silicate made of oxide such as Hf or Zr gets a lot of attention. For example, an example of using HfSiON (hafnium silicon oxynitride) which is oxide of Hf and Si as a gate insulating film has been proposed (refer to T. Watanabe et al., VLSI'03).

However, it is reported that when a high-k gate insulating film such as hafnium silicate is combined with a polysilicon (poly-Si) gate electrode, a flat band potential (Vfb) shifts and it is difficult to control a threshold by conducting ordinary channel ion implantation (refer to C. Hobbs et al., VLSI'03).

It is known that the Vfb shift does not occur if a metal gate electrode is used. However, when the metal gate electrode is used, a material having a work function suitable for threshold-voltage control for each of nMOS and pMOS is necessary.

Moreover, a fabrication method using a gate electrode made of a material completely silicided has been recently proposed. In the case of this method, the work function only becomes a vicinity of a mid-gap and it is difficult to control a threshold voltage. Moreover, an LSI is composed of a plurality of MOSFETs. In many cases, there are MOSFETs of a core portion each being operated at a low voltage and MOSFETs which are operated at a high voltage and are used for an input/output (I/O) portion.

Furthermore, three or more types of gate insulating film thicknesses may be used depending on an LSI. Because a MOSFET to be operated at a high power-supply voltage uses a gate insulating film thicker than a MOSFET to be operated at a low voltage, it is not always necessary to use a high-k material.

Therefore, a high-k gate insulating film is used for only a low-voltage-operating MOSFET in which a gate leak current affects performance, and a conventional oxide-film gate insulating film is used for a high-voltage-operating MOSFET. It is not preferable to use a metal gate electrode for these oxide-film gate insulating films in view of threshold voltage control and fabrication cost. It is difficult to realize a semiconductor device in which high-performance MOSFETs are integrated.

Moreover, Japanese Patent Laid-Open No. 2000-307010 discloses a semiconductor device which uses a silicon oxide film for the gate insulating film of an input/output portion composed of a high-voltage operation MOSFET, and a high-k-constant film having a different thickness for the internal-circuit gate insulating film composed of a low-voltage operation MOSFET. This semiconductor device uses a laminated structure made of a titanium nitride film and a tungsten film as the gate electrode for the low-voltage operation MOSFET, and a damascene process is used for semiconductor fabrication. Because of this, the high-k film is formed even on sidewalls of the gate electrode. The high-k film on the sidewalls of the gate electrode deteriorates a short channel property.

Furthermore, when an insulating film and an electrode film are embedded in a groove obtained by eliminating a dummy gate electrode, impurity distribution of a channel and an extension portion already formed fluctuates according to an oxidation process for forming the insulating film in the groove.

### SUMMARY OF THE INVENTION

A semiconductor device according to one embodiment of the present invention, comprising:
a semiconductor substrate;
a first MOSFET which has a first gate insulating film made of a high dielectric material formed above the semiconductor substrate and a first gate electrode formed above the first gate insulating film;
an insulating film which is formed directly on sidewalls of the first gate electrode and made of a material having dielectric constant smaller than that of the first gate insulating film; and
a second MOSFET which has a second gate insulating film made of a material having dielectric constant smaller than that of the first gate insulating film formed above the semiconductor substrate and a second gate electrode formed above the second gate insulating film,
wherein the first gate electrode is formed of a first silicide or a first metal; and
the second gate electrode is formed including a film made of at least one of polysilicon, amorphous silicon, polysilicon germanium and amorphous silicon germanium.

A method of fabricating a semiconductor device according to one embodiment of the present invention, comprising:
forming a high-k film above a first region of a semiconductor substrate, and forming an oxide film above a second region of the semiconductor substrate;
forming a pattern of a first gate electrode and a pattern of a second gate electrode above the high-k film and the oxide film, respectively, both made of at least one of polysilicon, amorphous silicon, polysilicon germanium and amorphous silicon germanium;
forming source and drain regions by using the patterns of the first and second gate electrodes as a mask;
siliciding wholly a film made of at least one of polysilicon, amorphous silicon, polysilicon germanium and amorphous silicon germanium constituting the pattern of the first gate electrode, and siliciding only a portion of a film made of at least one of polysilicon, amorphous silicon, polysilicon germanium and amorphous silicon germanium constituting the pattern of the second gate electrode.

### BRIEF DESCRIPTION OF THE DRAWINGS

FIGS. 1A and 1B are sectional views for explaining fabrication process of the semiconductor device according to first example of the present invention.

FIGS. 2A and 2B are sectional views for explaining fabrication process subsequent to FIGS. 1B.

FIGS. 3A and 3B are sectional views for explaining fabrication process subsequent to FIG. 2B.

FIG. 4 is a sectional view for explaining fabrication process subsequent to FIG. 3B.

FIGS. 5A-5C are sectional views for explaining fabrication process of the semiconductor device according to the second example of the present invention.

FIGS. 6A and 6B are sectional views for explaining a semiconductor device according to a third example of the present invention.

### DETAILED DESCRIPTION OF THE INVENTION

Hereinafter, embodiments of the present invention will be described with reference to drawings.

The semiconductor device according to an embodiment of the present invention is obtained by forming a plurality of MOSFETs to be driven by power-supply voltages of two or more types on the same semiconductor substrate. Among these MOSFETs, a MOSFET (low-voltage operating MOSFET) having a high-k gate insulating film has a metal gate electrode and a MOSFET (high-voltage operating MOSFET) having an oxide-film gate insulating film has a polysilicon gate electrode.

The semiconductor device according to this embodiment has a feature capable of keeping a high performance even if the device is miniaturized at low power consumption. A relative dielectric constant of the high-k gate insulating film in this case is 8 or more. Three specific embodiments of the present invention will be described below.

### First Example

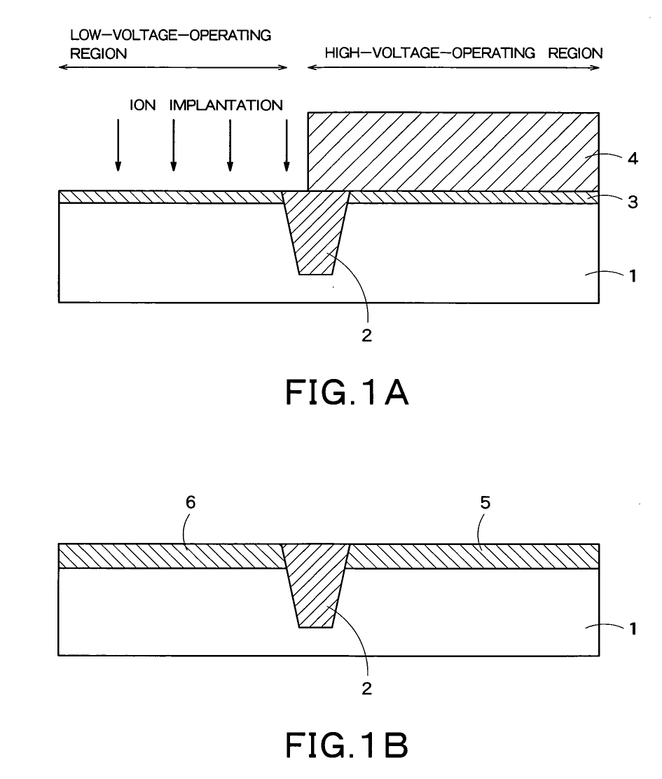

FIGS. 1 to 4 are sectional views for explaining the fabrication process of the semiconductor device according to first example of the present invention. First, a sacrifice oxide layer 3 having a thickness of 1 to 10 nm is formed by oxidation on a semiconductor substrate such as silicon on which a device separation region 2 such as STI (Shallow Trench Isolation) is formed on the surface area.

Then, a well region is formed and a threshold voltage is adjusted by performing ion implantation at a state of masking a predetermined device region with a photoresist 4 (FIG. 1A). Then, the sacrifice oxide film 3 is separated from the semiconductor substrate 1, heat treatment is applied to the semiconductor substrate 1 to form a silicon oxide film 5 having a thickness of 1 to 10 nm which serves as a gate insulating film. The silicon oxide film 5 becomes a thick gate insulating film for a high-voltage-operating MOSFET in a subsequent fabrication step. In this case, to decrease a gate leak current and keep impurity from penetrating from a gate electrode to the semiconductor substrate, nitrogen may be included in the gate insulating film to form a silicon oxynitride film. As a method of including nitrogen in the gate insulating film, a gas including nitrogen may be supplied when forming the oxide film, or the surface of the oxide film may be nitrided after the oxide film is formed.

Then, the gate insulating film (silicon oxide film 5) in the forming region (referred to as low-voltage operating region) of the low-voltage operating MOSFET is stripped, and a high-k film 6 made of hafnium silicon oxynitride (HfSiON) serving as a gate insulating film having a thickness of 0.1 to 10 nm is deposited. After depositing the high-k film 6, the high-k film 6 in the forming region (referred to as high-voltage operating region) of the high-voltage-operating MOSFET is selectively removed (FIG. 1B).

In FIG. 1B, an example is shown in which the upper face of the high-k film 6 in the low-voltage-operating region has almost the same height as the upper face of the silicon oxide film 5 in the high-voltage-operating region. However, it is not always necessary that the both upper faces have the same height. Although an example in which the high-k film 6 in the high-voltage-operating region is removed has been described, if the MOSFET can operate normally even if the high-k film 6 is not removed in terms of the operational voltage and the threshold voltage of the MOSFET, it is unnecessary to remove the high-k film 6 in the high-voltage-operating region.

Then, a polysilicon film 7 having a thickness of 20 to 200 nm to serve as a gate electrode is deposited above the semiconductor substrate 1. Instead of the polysilicon film, it may be possible to deposit an amorphous silicon film, polysilicon germanium or amorphous silicon germanium. Or a laminated film including these films may be deposited.

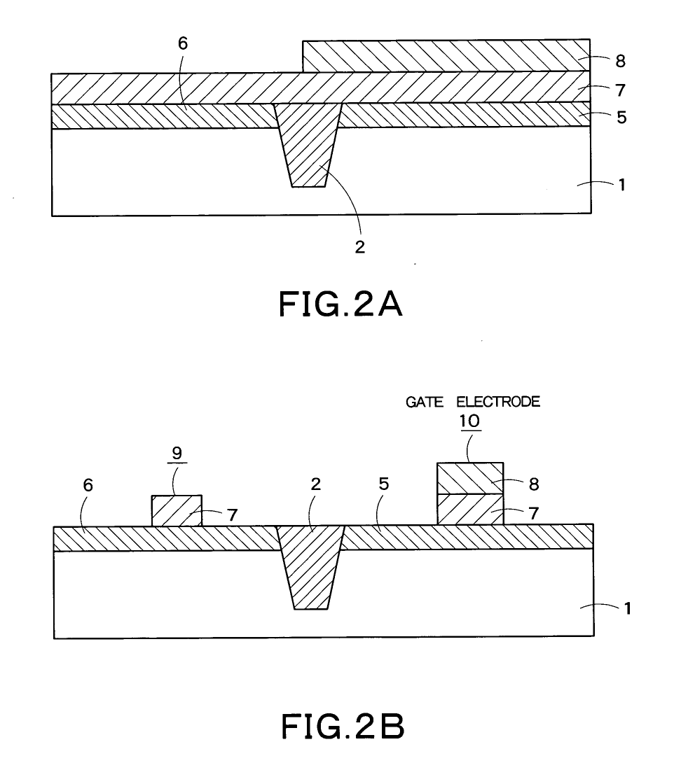

Thereafter, an insulting film 8 such as a silicon nitride film or silicon oxide film having a thickness of 10 to 200 nm is deposited on the polysilicon film 7. Then, the insulating film 8 in the low-voltage-operating region, that is, the insulating film 8 located above the high-k film 6 is removed (FIG. 2A).

Then, the polysilicon film 7 and the insulating film 8 are patterned by using the normal photolithography technique to form patterns of gate electrodes 9 and 10 (FIG. 2B). In this case, the MOSFET in the high-voltage-operating region, that is, the MOSFET having an oxide-film gate insulating film has the pattern of the gate electrode 10 having a structure in which the insulating film 8 is laminated on the polysilicon film 7, and the MOSFET in the low-voltage-operating region has the pattern of the gate electrode 9 made of only the polysilicon film 7.

Then, after a shallow diffusion region 11 serving as source/drain region is formed by implanting impurity ions, sidewall insulating films 12 and 13 are formed beside the patterns of the gate electrodes 9 and 10. The sidewall insulating films 12 and 13 may be made of one type material or a plurality of materials. As a material of the sidewall insulating films 12 and 13, a material having dielectric constant smaller than that of the high-k film 6 such as silicon oxide film or silicon nitride film is used.

As described above, in the low-voltage-operating region, after the gate electrode 9 is formed on the high-k film 6, the sidewall insulating film 12 is formed beside the pattern of the gate electrode 9 by using the material having dielectric constant smaller than that of the high-k film 6. Therefore, no high-k film is formed on the sidewall of the pattern of the gate electrode 9, thereby preventing the short channel property from being deteriorated.

Thereafter, by implanting impurity ions, a deep diffusion region 14 serving as source/drain region is formed. Insulating film (silicon oxide film 5 and high-k film 6) in regions other than a forming region of the gate structure (the patterns of the gate electrodes 9 and 10) are removed among insulating films formed on the surface of the semiconductor substrate 1 before or after forming the deep diffusion region 14.

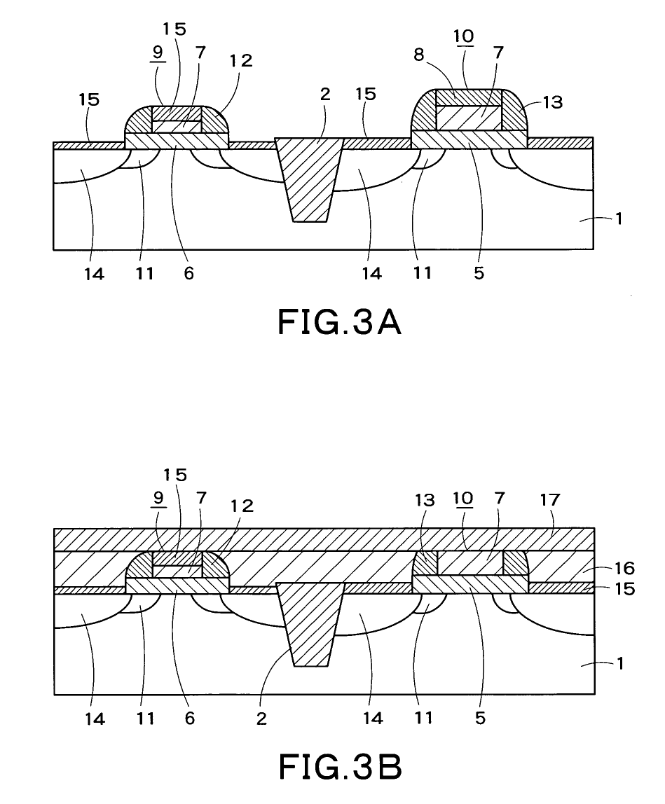

Then, by depositing a metal film (not illustrated) of Ni, Pt, Ti, and Co by approx. 1 to 20 nm and performing heat treatment, a suicide layer 15 is formed on the upper face of the diffusion region 14 and the surface of the polysilicon film 7 not covered with the insulating film 8 (FIG. 3A).

Thereafter, an insulating film 16 such as a silicon oxide film is deposited on the surface of the semiconductor substrate 1 to cover MOSFETs. Then, the deposited insulating film 16 is removed until the material of the gate electrodes 9 and 10 of the MOSFETs is exposed in accordance with a flattening process such as CMP.

By this treatment, the silicide layer 15 which is a material of the gate electrode 9 of the MOSFET using the high-k film 6 serving as the gate insulating film is exposed in the low-voltage-operating region, and the polysilicon film 7 which is a material of the gate electrode 10 of the MOSFET using the silicon oxide film 5 serving as the gate insulating film is exposed in the high-voltage-operating region. In this case, the insulating film 8 deposited on the polysilicon film 7 is also simultaneously removed.

Thereafter, a metal film 17 made of Ni, Pt, Ti, and Co for forming silicide is deposited above the semiconductor substrate 1 again. The metal film 17 causes a silicide reaction only by the gate electrodes 9 and 10 (FIG. 3B). In this case, by optimizing the thickness, heat treatment temperature and time of the deposited metal film 17, only a part of the polysilicon film 7 of the gate electrode 10 of the MOSFET in the high-voltage-operating region is only silicided but the entire film is not silicided. However, the polysilicon film 7 of the gate electrode 9 of the MOSFET in the low-voltage-operating region is fully silicided.

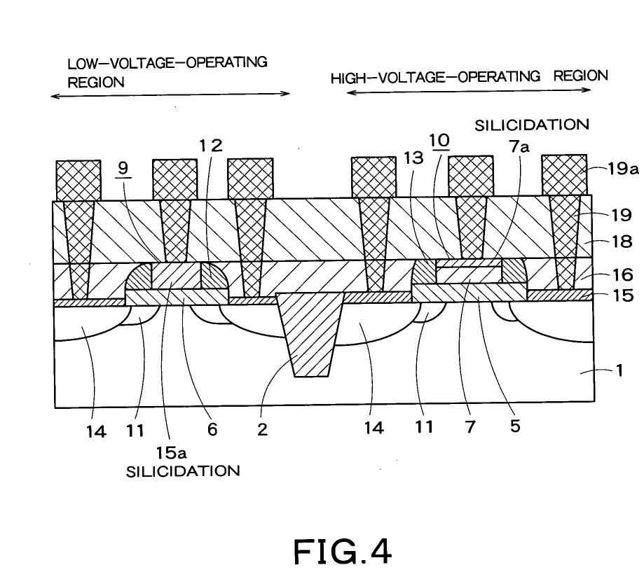

Thus, the gate electrode 9 is made of only a silicide layer 15a and the gate electrode 10 is made of the polysilicon film 7 and a silicide layer 7a formed on the polysilicon film 7 (FIG. 4). This is because the silicide layer 15 is previously formed on the gate electrode 9 of the MOSFET having a gate insulating film made of the high-k film 6 before starting the process in FIG. 3B and the gate electrode 9 is completely silicided in a shorter time or by the thinner metal film 17 than the gate electrode 10 of the MOSFET having a gate insulating film made of oxide film 5.

Then, the MOSFET on the semiconductor substrate 1 is covered by depositing an insulating film 18 such as a silicon oxide film on the entire upper face of the semiconductor substrate 1. Then after the insulating film 18 is flattened, contact holes are formed at predetermined locations. Therefore, the silicide layers 15, 15a and 7a are exposed on the gate electrodes 9 and 10 and the impurity diffusion region 14. A contact hole is formed through anisotropic etching such as RIE.

Then, metal such as tungsten is embedded in the contact hole as a connection wiring 19 to connect with the outside. Then, a wiring pattern 19a is formed on the surface of the flattened insulating film 18. The wiring pattern 19a includes an external connection terminal and is electrically connected to the gate electrodes 9 and 10 and the impurity diffusion region 14 via the connection wiring 19. Thereafter, a semiconductor device is completed by the conventionally-known ordinary MOSFET fabrication process (FIG. 4).

According to this example, it is possible to form a low-voltage-operating MOSFET having a gate insulating film made of the high-k film 6 and the gate electrode 9 made of the silicide layer 15a, and a high-voltage-operating MOSFET having a gate insulating film made of the silicon oxide film 5 and the gate electrode 10 made of the polysilicon film 7 on the same semiconductor substrate. Thereby, it is possible to fabricate a semiconductor device capable of keeping a high performance even if the device is miniaturized and power consumption is reduced.

More specifically, according to this example, it is possible to form a main circuit such as a logic circuit or memory circuit using a low-voltage-operating MOSFET operated at approx. 1 to 1.2 V and a peripheral circuit such as I/O using a high-voltage-operating MOSFET operated at 2.5 to 3.3 V in one silicon chip, for example, and these circuits can be optimized. That is, because the low-voltage-operating MOSFET has a gate insulating film made of the high-k film 6, it is possible to restrain gate leak even if decreasing the thickness of the gate insulating film. Moreover, because the high-voltage-operating MOSFET has a gate insulating film made of the slightly-thick silicon oxide film 5 and a gate electrode 10 made of the polysilicon film 7, a high withstand voltage is kept and the controllability of a threshold voltage is improved.

In the case of the above example, hafnium silicate is used as a high-k gate insulating film. However, it may be possible to use a material other than hafnium silicon oxynitride as long as the material can achieve a desired gate leak current. For example, it may be possible to use any one of HfO₂, ZrO₂, Al₂O₃, La₂O₃, and Ta₂O₅ or a material other than these materials.

Moreover, as the metallic material forming of the silicide it may be possible to use Ir, ER, Yb, Y, Ru, Ta or the other material other than the above-described Ti, Co, Ni, and Pt. Furthermore, as the material of the gate electrodes 9 and 10, it may be possible to use a metal-nitride such as TaN or TiN, a boride such as TiB or TaB, or a metal such as W or Mo other than the above-described silicide. Furthermore it may be possible to differentiate the metal used for an N-type MOSFET from the metal used for a P-type MOSFET.

### Second Example

Second example described below is different from the first example in the structure of a high-voltage-operating MOSFET.

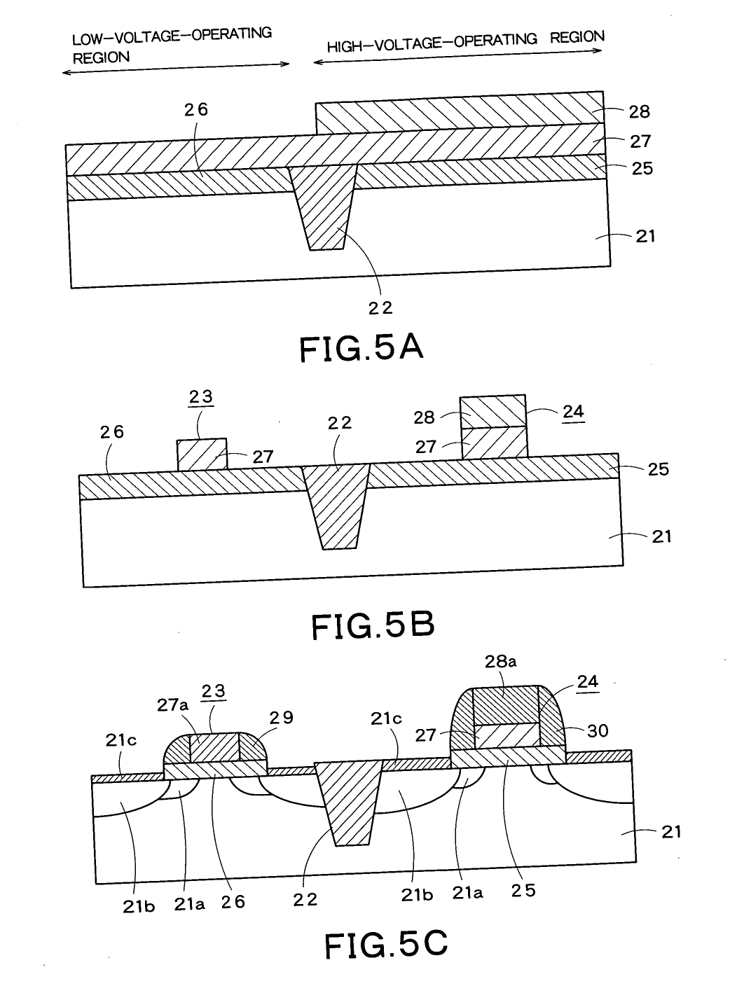

FIGS. 5A-5C are sectional views for explaining fabrication process of the semiconductor device according to the second example of the present invention. In the case of this example, polysilicon is used as the starting material of a gate electrode for a low-voltage-operating MOSFET and a film obtained by containing germanium in polysilicon is used for a high-voltage-operating MOSFET. Moreover, the whole gate electrode is silicided for the low-voltage-operating MOSFET but only a part of a gate electrode is silicided for the high-voltage-operating MOSFET.

This example is the same as the first example in steps of forming a plurality of gate insulating films and depositing the polysilicon film made of a gate electrode. A high-k film 26 such as hafnium silicon oxynitride (HfSiON) having a thickness of 0.1 to 10 nm serving as the gate insulating film is formed in the low-voltage-operating region on the surface of a semiconductor substrate 21 made of silicon or the like on which a device separation region 22 such as STI is formed and a silicon oxide film 25 having a thickness of 1 to 10 nm serving as the gate insulating film made of a silicon oxide film is formed in the high-voltage-operating region.

After forming the high-k film 26, a polysilicon film 27 having a thickness of 20 to 100 nm serving as a gate electrode is deposited on the semiconductor substrate 21. Thereafter, a polysilicon germanium film 28 having a thickness of 20 to 100 nm is deposited on the polysilicon film 27. The polysilicon germanium film 28 is shown by a general expression of SixGel−x (0<x<1). It is possible to properly select the Ge concentration in a film in the range of x. Then, a portion covering the low-voltage-operating region of the polysilicon germanium film 28 is removed through etching (FIG. 5A).

Then, the polysilicon film 27 and polysilicon germanium film 28 are patterned by using the normal photolithography technique and a pattern of a gate electrode 23 made of the polysilicon film 27 is formed in the low-voltage-operating region and a pattern of a gate electrode 24 having the polysilicon film 27 and the polysilicon germanium film 28 laminated on the polysilicon film 27 is formed in the high-voltage-operating region.

Thereby, the gate electrode of the high-voltage-operating MOSFET becomes higher than the gate electrode of the low-voltage-operating MOSFET by a value at which the polysilicon germanium film 28 is formed (FIG. 5B).

Then, using the patterns of the gate electrodes 23 and 24 as a mask, a shallow impurity diffusion region 21a is formed by impurity ion implantation and thermal diffusion methods. Thereafter, sidewall insulating films 29 and 30 such as silicon nitride films are formed beside the patterns of the gate electrodes 23 and 24.

Thereafter, using the sidewall insulating films 29 and 30 as a mask, a deep impurity diffusion region 21b is formed by impurity ion implantation and thermal diffusion methods. The shallow impurity diffusion region 21a and deep impurity diffusion region 21b constitute the source/drain region of a MOSFET.

Then, the silicon oxide films 25 and the high-k film 26 other than an region in which a gate structure made of a gate insulating film, gate electrode, and a sidewall insulating film is formed are removed from the surface of the semiconductor substrate 21. Similarly to the first example, the removal of the silicon oxide films 25 and the high-k film 26 may be performed before forming the source/drain region. Then, metal films made of Ni, Pt, Ti, Co and the like are deposited on the impurity diffusion region 21b on the surface of the semiconductor substrate 21 and the patterns of the gate electrodes 23 and 24 to perform a heat treatment.

Thereby, a silicided layer 21c is formed on the impurity diffusion region 21b, the polysilicon film of the gate electrode 23 of the low-voltage-operating MOSFET are wholly silicided to form a silicide layer 27a, and the polysilicon germanium film of the gate electrode 24 of the high-voltage-operating MOSFET and a part of the polysilicon film are silicided to form a silicided layer 28a. However, a portion contacting the gate insulating film 25 of the polysilicon film 27 is not silicided and a polysilicon film 27 remain in the high-voltage-operating region. The silicide layer 21c on the impurity diffusion region 21b is formed of the same material as the silicide constituting a gate electrode (FIG. 5C).

Thus, in the case of this example, the low-voltage-operating MOSFET having a gate insulating film of a high-k film has a gate electrode film thickness smaller than that of the high-voltage-operating MOSFET having a gate insulating film made of a silicon oxide film. Therefore, even if a salicide process is normally performed, all gate electrodes of the low-voltage-operating MOSFET are silicided. By optimizing a deposited metal film, heat-treatment temperature and time, it is possible to realize a process having a sufficient margin. Moreover, according to this example, because a step (refer to FIG. 3B) of flattening the upper portion of a gate electrode in order to expose the upper portion like the case of the first example becomes unnecessary, the fabrication process can be simplified.

### Third Example

A third example described below forms a MOSFET on an SOI substrate.

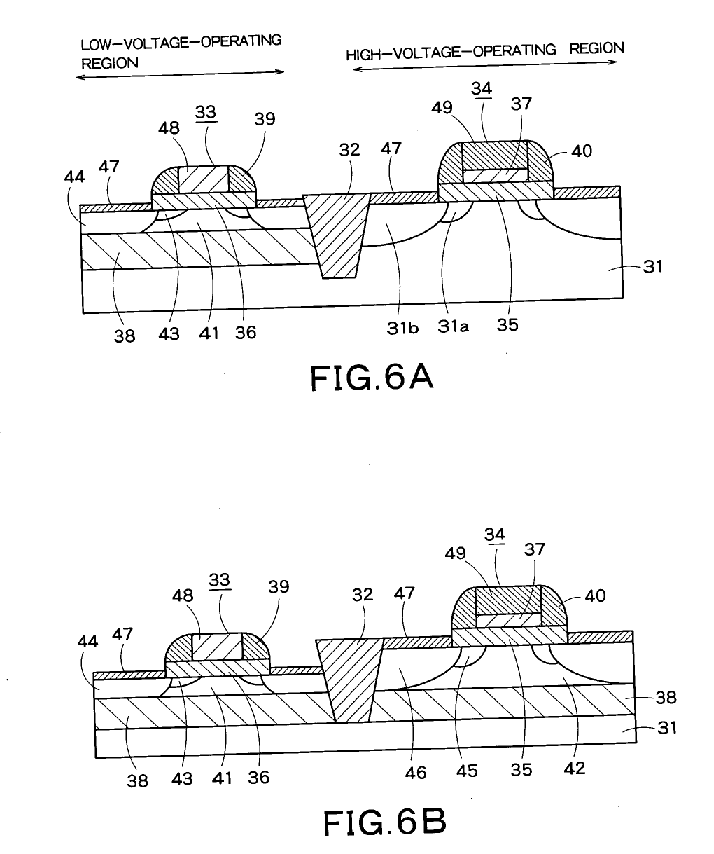

FIGS. 6A and 6B are sectional views for explaining a semiconductor device according to the third example of the present invention. In the case of the semiconductor device shown in FIG. 6A, the SOI substrate is provided in a low-voltage-operating region. A device separation region 32 such as STI is formed on the surface region of a semiconductor substrate 31 made of silicon or the like. A MOSFET (low-voltage-operating MOSFET) having a gate insulating film made of a high-k film is formed in a low-voltage-operating region on the SOI substrate and a MOSFET (high-voltage-operating MOSFET) having a gate insulating film made of a silicon oxide film is formed on the normal bulk substrate.

The SOI substrate in the low-voltage-operating region has an insulating layer 38 such as a silicon oxide film formed on the semiconductor substrate 31 and a silicon layer 41 formed on the insulating layer 38. A shallow impurity diffusion region 43 serving as source/drain region and a deep impurity diffusion region 44 are formed on the silicon layer 41, a gate insulating film constituted of a high-k film 36 having a thickness of about 0.1 to 10 nm is formed between the impurity diffusion regions, and a gate electrode 33 made of a silicide layer 48 of any one of metals such as Ni, Pt, Ti, and Co is formed on the gate insulating film. A sidewall insulating film 39 such as a silicon nitride film is formed on the side (beside) of the gate electrode 33. Moreover, a silicide layer 47 made of the same material as the silicide of the gate electrode is formed on the deep impurity diffusion region 44.

A shallow impurity diffusion region 31a and deep impurity diffusion region 31b serving as source/drain region are formed on the high-voltage-operating region, a gate insulating film made of a silicon oxide film 35 having a thickness of about 1 to 10 nm is formed between the impurity diffusion regions, and a gate electrode 34 made of the polysilicon film 37 and a silicide layer 49 of metal selected from Ni, Pt, Ti, and Co on the film 37 is formed on the gate insulating film. A sidewall insulating film 40 such as a silicon nitride film is formed on the side of (beside) the gate electrode 34. Moreover, the silicide layer 47 made of the same material as the silicide layer of the gate electrode 34 is formed on the deep impurity diffusion region 31b.

In the case of the semiconductor device shown in FIG. 6B, an SOI substrate is provided on low-voltage-operating region and high-voltage-operating region. The device separation region 32 such as STI is formed on the semiconductor substrate 31 at the boundary between the low-voltage-operating region and the high-voltage-operating region, a low-voltage-operating MOSFET is formed on the SOI substrate in the low-voltage-operating region, and a high-voltage-operating MOSFET is formed on the SOI substrate in the high-voltage-operating region.

The SOI substrate in the low-voltage-operating region has the same structure as that in FIG. 6A. The SOI substrate in the high-voltage-operating region has the insulating layer 38 made of a silicon oxide film formed on the semiconductor substrate 31 and a silicon layer 42 formed on the layer 38. The silicon layer 42 is deposited thicker than the silicon layer 41 in the low-voltage-operating region. A shallow impurity diffusion region 45 and deep impurity diffusion region 46 serving as source/drain region are formed on the silicon layer 42. A gate insulating film made of the silicon oxide film 35 having a thickness of about 1 to 10 nm is formed on the surface between the impurity diffusion regions 45 and 46, and the gate electrode 34 made of the polysilicon 37 and suicide layer 49 is formed on the gate insulating film. The silicide layer 49 is a silicide layer of metal selected from Ni, Pt, Ti, and Co. The side-wall insulating film 40 such as a silicon nitride film is formed on the side of (beside) the gate electrode 34. Moreover, the silicide layer 47 made of the same material as the silicide layers 48 and 49 of the gate electrode is formed on the deep impurity diffusion region 45.

In the case of this example, it may be possible to use any of steps described for examples 1 and 2 as a gate-electrode siliciding step. Moreover, the MOSFET on the SOI substrate may be a partially depleted type or a fully depleted type. In terms of obtaining a stable threshold voltage, the fully depleted type is more suitable than the partially depleted type.

Here, the fully depleted type denotes a state in which insides of the silicon layers 41 and 42 of the SOI substrate are fully depleted and the partially depleted type denotes a state in which carriers are present in a part of the silicon layer 41 or 42. The fully depleted type or partially depleted type is decided in accordance with thicknesses of the silicon layers 41 and 42 and the gate length of a MOSFET.

In the case of the partially depleted type, because carriers caused by impact ionization are accumulated in the silicon layers 41 and 42, a substrate potential may fluctuate and a threshold voltage may change. However, it is possible to stabilize the threshold voltage by forming a contact for controlling the substrate potential. This characteristic is important in the case of forming an electrostatic discharge protection circuit. It is desirable to use the partially depleted type to a circuit requiring a high withstand voltage.

Therefore, in the case of this example, the low-voltage-operating MOSFET is set to the fully depleted type and the high-voltage-operating MOSFET is set to the partially depleted type.

In the case of the fully depleted type MOSFET, it is preferable that the work function of a gate electrode is close to Mid-gap. This example can easily realize it.

Moreover, a peripheral circuit such as an I/O portion requires an operation at a higher power-supply voltage and a plurality of threshold voltages. Therefore, it is preferable to use a partially depleted type MOSFET, and it is more preferable to use polysilicon than metal as a gate electrode. Thereby, degree of freedom for controlling the threshold voltage increases, the parasitic capacitance of an impurity diffusion region is decreased, and high speed operation can be realized, compared with the conventional device.

When fabricating a semiconductor device having the structure shown in FIG. 6A, an SOI substrate, a part of which is used for the low-voltage-operating region, is prepared, and then the insulating layer 38 and silicon layer 41 corresponding to the high-voltage-operating region in the SOI substrate are removed. Next, a silicon layer is crystal-grown to form bulk silicon substrate in the high-voltage-operating region, and a MOSFET is formed on the substrate.

On the other hand, when fabricating a semiconductor device having the structure shown in FIG. 6B, an SOI substrate having a slightly-thick silicon layer 42 is prepared and a part of a silicon layer corresponding to the low-voltage-operating region is removed to form a thinner silicon layer 41, and then a MOSFET is formed.

Thus, in the case of this example, a MOSFET in the low-voltage-operating region is formed of an SOI substrate to realize a fully depleted type SOI structure. Because of this, it is possible to easily miniaturize the MOSFET and restrain the fluctuation of a threshold voltage. Moreover, because a MOSFET in the high-voltage-operating region is formed of bulk or an SOI structure of the partially depleted type, a high-speed operation is realized.

What is claimed is:

1. A semiconductor device, comprising:
a semiconductor substrate;
a first MOSFET which has a first gate insulating film made of a high dielectric material formed above the semiconductor substrate and a first gate electrode formed above the first gate insulating film;
an insulating film which is formed directly on sidewalls of the first gate electrode and made of a material having dielectric constant smaller than that of the first gate insulating film; and
a second MOSFET which has a second gate insulating film made of a material having dielectric constant smaller than that of the first gate insulating film formed above the semiconductor substrate and a second gate electrode formed above the second gate insulating film,
wherein the first gate electrode is formed of a first silicide or a first metal; and
the second gate electrode is formed including a film made of at least one of polysilicon, amorphous silicon, polysilicon germanium and amorphous silicon germanium.

2. The semiconductor device according to claim 1,
wherein the second gate electrode has a film made of a second silicide or a second metal formed on the film made of at least one of polysilicon, amorphous silicon, polysilicon germanium and amorphous silicon germanium.

3. The semiconductor device according to claim 1,
wherein the first gate insulating film has a relative dielectric constant more than 8.

4. The semiconductor device according to claim 2,
wherein the second silicide or second metal in the second gate electrode is made of the same material as that of the first gate electrode.

5. The semiconductor device according to claim 1,
wherein a physical film thickness of the second gate electrode is thicker than that of the first gate electrode.

6. The semiconductor device according to claim 5,
wherein all of the first gate electrode is wholly silicided; and
the second gate electrode has a silicide layer formed on the film made of at least one of polysilicon, amorphous silicon, polysilicon germanium and amorphous silicon germanium.

7. The semiconductor device according to claim 1,
wherein the first MOSFET is formed on an SOI substrate having a buried insulating film formed on the semiconductor substrate and a semiconductor film formed on the buried insulating film; and
the second MOSFET is formed on the semiconductor substrate.

8. The semiconductor device according to claim 1,
wherein each of the first and second MOSFETs is formed on an SOI substrate which has a buried insulating film formed on the semiconductor substrate and a semiconductor film formed on the buried insulating film.

9. The semiconductor device according to claim 8,
wherein the first MOSFET has a fully depleted type SOI structure; and
the second MOSFET has a partially depleted type SOI structure.

10. The semiconductor device according to claim 8,
wherein the semiconductor film in a forming region of the first MOSFET is thinner than the semiconductor film in a forming region of the second MOSFET.

11. A method of fabricating a semiconductor device, comprising:
forming a high-k film above a first region of a semiconductor substrate, and forming an oxide film above a second region of the semiconductor substrate;
forming a pattern of a first gate electrode and a pattern of a second gate electrode above the high-k film and the oxide film, respectively, both made of at least one of polysilicon, amorphous silicon, polysilicon germanium and amorphous silicon germanium;
forming source and drain regions by using the patterns of the first and second gate electrodes as a mask;
siliciding wholly a film made of at least one of polysilicon, amorphous silicon, polysilicon germanium and amorphous silicon germanium constituting the pattern of the first gate electrode, and siliciding only a portion of a film made of at least one of polysilicon, amorphous silicon, polysilicon germanium and amorphous silicon germanium constituting the pattern of the second gate electrode.

12. The method of fabricating a semiconductor device according to claim 11,
wherein after forming the pattern of the first gate electrode above the high-k film and before siliciding wholly the film made of at least one of polysilicon, amorphous silicon, polysilicon germanium and amorphous silicon germanium, a metal film is formed on the film made of at least one of polysilicon, amorphous silicon, polysilicon germanium and amorphous silicon germanium constituting the pattern of the first gate electrode, and a silicide layer is formed in a surface of the film made of at least one of polysilicon, amorphous silicon, polysilicon germanium and amorphous silicon germanium by performing heat treatment.

13. The method of fabricating a semiconductor device according to claim 11,
wherein the high-k film is formed of an insulating film having a relative dielectric constant more than 8.

14. The method of fabricating a semiconductor device according to claim 11,
wherein a silicided layer formed partially in the second gate electrode is the same material as that of a silicided layer formed wholly in the first gate electrode.

15. The method of fabricating a semiconductor device according to claim 11,
wherein a film thickness of the second gate electrode is thicker than that of the first gate electrode.

16. The method of fabricating a semiconductor device according to claim 11,
wherein a silicide layer is formed on a portion of a film obtained by laminating silicon germanium on silicon in the second gate electrode.

17. The method of fabricating a semiconductor device according to claim 11,
wherein a first MOSFET having the high-k film and the first gate electrode is formed on an SOI substrate which has a buried insulating film formed on the semiconductor substrate and a semiconductor film formed on the buried insulating film; and
a second MOSFET having the oxide film and the second gate electrode is formed on the semiconductor substrate.

18. The method of fabricating a semiconductor device according to claim 11,
wherein a first MOSFET having the high-k film and the first gate electrode and a second MOSFET having the oxide film and the second gate electrode are formed on an SOI substrate which has a buried insulating film formed on the semiconductor substrate and a semiconductor film formed on the buried insulating film.

19. The method of fabricating a semiconductor device according to claim 18,
wherein the first MOSFET has a fully depleted type SOI structure; and
the second MOSFET has a partially depleted type SOI structure.

20. The method of fabricating a semiconductor device according to claim 18,
wherein the semiconductor film in the first region is thinner than the semiconductor film in the second region.
